(19) United States
(12) Patent Application Publication
(10) Pub. No.: US 2023/0290765 A1
(43) Pub. Date: Sep. 14, 2023

(54) INTEGRATED CIRCUIT PACKAGE WITH BACKSIDE LEAD FOR CLOCK TREE OR POWER DISTRIBUTION NETWORK CIRCUITS

(71) Applicant: Microchip Technology Incorporated, Chandler, AZ (US)

(72) Inventors: Justin Sato, West Linn, OR (US); Bomy Chen, Newark, CA (US); Julius Kovats, Manitou Springs, CO (US); Anu Ramamurthy, Newbury Park, CA (US)

(73) Assignee: Microchip Technology Incorporated, Chandler, AZ (US)

(21) Appl. No.: 18/064,971

(22) Filed: Dec. 13, 2022

Related U.S. Application Data
(60) Provisional application No. 63/319,308, filed on Mar. 12, 2022.

(51) Int. Cl. H01L 25/18; H01L 25/065; H01L 23/498; H01L 23/00; H01L 25/00

(52) U.S. Cl. CPC H01L 25/18; H01L 25/0652; H01L 23/49811; H01L 24/40; H01L 24/16; H01L 24/73; H01L 24/48; H01L 24/37; H01L 24/84; H01L 24/95; H01L 25/50; H01L 2224/16225; H01L 2224/37147; H01L 2224/40235; H01L 2224/48245; H01L 2224/73255; H01L 2224/40105; H01L 2224/40137; H01L 2224/40499; H01L 2924/0105; H01L 2224/84201; H01L 2224/95; H01L 2224/84007; H01L 23/49827; H01L 23/481

(57) ABSTRACT

An apparatus having a substrate having first and second substrate contacts; a chip having a front-side chip contact and first and second back-side chip contacts, the front-side chip contact electrically connected to the first substrate contact; a chiplet having a chiplet contact electrically connected the first back-side chip contact; and a lead electrically connected to the second back-side chip contact and electrically connected to the second substrate contact.

### RELATED APPLICATION

This application is a Continuation-in-Part of U.S. patent application Ser. No. 17/665,749, filed Feb. 7, 2022, which claims priority to U.S. Patent Application No. 63/249,854, filed Sep. 29, 2021, the entire contents of which are hereby incorporated by reference for all purposes. This application is a Continuation-in-Part of U.S. patent application Ser. No. 17/667,275, filed on Feb. 8, 2022, which claims priority to U.S. Patent Application No. 63/251,412, filed on Oct. 1, 2021, the entire contents of which are hereby incorporated by reference for all purposes.

### TECHNICAL FIELD

The present disclosure relates to integrated circuit (IC) packages, and more particularly to an IC package having a backside lead for power via clock.

### BACKGROUND

An integrated circuit (IC) package includes various elements assembled together in a package suitable for handling or mounting on a printed circuit board (PCB) or other support structure. The elements of an IC package are referred to herein as “integrated circuit package devices” or “IC package devices.” Some example types of IC package devices include IC dies (also referred to as chips), passive interposers (interposers including passive electrical routing elements, resistors, capacitors, and inductors), and active interposers (interposers including electrical routing elements as well as active circuit elements, e.g., transistors, voltage regulators, or input/output controllers, without limitation).

IC package devices may be arranged and packaged in various manners to form various different types of IC packages, including DIP (Double In-line Package), SOP/SOIC/SO (Small Outline Package/Small Outline Integrated Circuit/Small Outline), QFP (Quad Flat Package), QFN/LCC (Quad Flat Non-leaded Package/Leadless Chip Carrier), BGA (Ball Grid Array Package), CSP (Chip Scale Package), and SiP (System-in-Package), among many others.

Moore's law suggests that the number of transistors in a dense IC doubles about every two years. It is increasingly expensive to produce smaller transistors and smaller transistors may not be compatible or efficient with certain transistor structures, such as RibbonFET or FinFETs. Thermal constraints limit gate-all-around (GAA)/RibbonFET die designs. Certain structures, particularly long channel, large area Power Distribution Network (PDN) and Clock-Tree integrated circuits (IC) tend to induce hot spots in a die, particularly in 20 Angstrom/18 Angstrom and smaller. Dense front-end-of-line (FEOL) metal pitch further limits RibbonFET and FinFET designs, in particular, where the complementary metal-oxide-semiconductor (CMOS) of a known-good-die (KGD) (e.g., PDN or Clock-Tree) is in the IC die. PowerVia is a backside power delivery scheme and RibbonFET is a transistor technology based on GAA transistors, both by Intel Corporation. At the time of the present application, a most advanced IC die is 5^{˜}3 nm CMOS, an advanced IC die is a 300 mm wafers IC produced during the recent 5˜10 years like 90 nm˜16 nm, and a Legacy IC die is a 6″-8″ silicon wafer technology node (insulated-gate bipolar transistor 350 nm˜110 nm).

A chiplet is a tiny integrated circuit (IC) that contains a well-defined subset of functionality. It is designed to be combined with other chiplets on an interposer in a single package. A set of chiplets can be implemented in a mix-and-match “LEGO-like” assembly. Certain structures, particularly Power Distribution Network (PDN) and Clock-Tree integrated circuits (IC) may be disaggregated into respective chiplets.

There is a need for a backside power delivery method in IC packages, in particular, for (RibbonFET) or fin-shaped field-effect transistor (FinFET) transistor architectures implementing Power Distribution Network (PDN) and Clock-Tree circuit functionality.

### SUMMARY

According to one aspect, there is provided an integrated circuit package, including: an integrated circuit package device including a chip, a substrate, and a contact element or lead, the contact element or lead bonded to a back-side of the chip, the integrated circuit package comprises disaggregated parts including: a clock tree, a power distribution network (PDN), and a low drop-out linear regulator (LDO) for power management, wherein the contact element or lead is attached to a through-silicon via (TSV) pad of an Advanced IC die.

An aspect provides an apparatus comprising: a substrate having first and second substrate contacts; a chip having a front-side chip contact and first and second back-side chip contacts, the front-side chip contact electrically connected to the first substrate contact; a chiplet having a chiplet contact electrically connected the first back-side chip contact; and a lead electrically connected to the second back-side chip contact and electrically connected to the second substrate contact

According to another aspect, there is provided a method comprising: mounting a front-side of a chip to a substrate, wherein the chip has a front-side chip contact and first and second chip back-side contacts and the substrate has first and second substrate contacts; electrically connecting the front-side chip contact to the first substrate contact; mounting a chiplet to a back-side of the chip, wherein the chiplet has a chiplet contact; electrically connecting the chiplet contact to the first chip back-side contact; and electrically connecting a lead to the second back-side chip contact and to the second substrate contact, wherein the lead is capable of conducting power to the chip.

Another aspect provides a system comprising: a substrate having first and second substrate contacts; a chip having a front-side chip contact and first, second, and third back-side chip contacts, the front-side chip contact electrically connected to the first substrate contact; a clock tree chiplet having a clock tree chiplet contact electrically connected the first back-side chip contact, wherein the clock tree chiplet comprises a clock tree circuit; a power distribution network chiplet having a power distribution network contact electrically connected the third back-side chip contact, wherein the power distribution network chiplet comprises a power distribution network circuit; and a lead electrically connected to the second back-side chip contact and electrically connected to the second substrate contact.

### BRIEF DESCRIPTION OF THE FIGURES

The figures illustrate integrated circuit (IC) packages, and more particularly show an IC package module including power via clock package.

FIG. 1 is a cross-sectional side view of an integrated circuit (IC) package with a stamped copper clip lead frame connecting a redistribution layer to a substrate.

FIG. 2A is a side view of an IC package having chiplets wire bonded to the lead frame.

FIG. 2B is a top view of the IC package of FIG. 2A.

FIG. 3 is a cross-sectional side view of an IC package having chiplets bonded directly to chips, with copper leads connecting back-sides of the chips to a substrate.

FIG. 4 shows a cross-sectional side view of a two-side (two lead frame) QFN package, wherein a backside copper lead frame provides a path for Power vIa Clock on both sides of the substrate.

FIGS. 5A and 5B show side views of a 3D printed dish for holding the copper lead frame in position to make the package.

FIG. 6 shows a cross-sectional side view of a tape for bonding the copper lead frame.

FIG. 7 is a cross-sectional side view of a tape in a pattern for bonding the copper lead frame.

FIG. 8A shows a cross-sectional side view of an IC package, wherein a flexible tape is aligned and placed over the package substrate for bonding the copper lead frame.

FIG. 8B shows a cross-sectional side view of the IC package of FIG. 8A, wherein insulator and solder layers are positioned on the package.

FIG. 9 shows a cross-sectional side view of a package wherein tape bonds a leadframe to the substrate and chips.

FIG. 10 illustrates method steps for pre-coating solder paste on an organic substrate's power redistribution layer for bonding a copper clip or lead frame.

FIG. 11 shows an algorithm for manufacturing an IC package by mounting a chip on a substrate, mounting a chiplet on the chip, and connecting a lead from the chip to the substrate.

FIG. 12 shows an IC package having a chip on a substrate, a chiplet on the chip, and a lead from the chip to the substrate.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

The present disclosure provides an IC package including an IC package device and a bonding system for bonding the IC package device to other IC package devices in the IC package. The bonding system may include at least one bonding element array, including at least one multi-component bonding element comprising a conduction component and a bonding component. IC packages including at least one IC package device are also provided, along with methods for forming IC packages, such as bonding methods.

Dense front-end-of-line (FEOL) metal pitch may benefit from backside power delivery, where power/ground lines are wired from wafer/IC backside through redistribution layers (RDL) and through-silicon vias (TSVs). Thermal constraints become an important concern for gate-all-around (GAA)/RibbonFET dies. Certain structures, particularly a power distribution network (PDN) and Clock-Tree ICs may be good candidates for disaggregation into chiplets, i.e. into an IC that contains a well-defined functionality, which is designed to be combined with other chiplets in an IC package. Removal of clock tree and power distribution networks from the front-side of a chip or IC die within a package may free up important real estate on an IC die and remove some waste heat from the IC die.

Aspects may provide a way of attaching power to provide various supply DC voltages and ground, wherein Vdd could be any of 5V/3.3V/1.8V/1.2V, may also supply half of Vdd or an Analog-Vdd or a Digital-Vdd from a Power Management IC chiplet, such as low drop-out linear regulators (LDO). Thermal vias may reduce thermal resistance that release waste heat from an IC to the environment. If thermal vias can also provide DC voltage or ground connections, those vias may have very low Ohmic resistance. Attaching ground and power through thermal vias to the package substrate or printed circuit board (PCB) through wire bond or lead frame may provide a good ground and improved resistance. By routing the ground and power from the backside of the substrate through the redistribution layers (RDL) and through-silicon vias (TSVs) to the FEOL, metal performance (layout and resistance-capacitance product (RC)) may be improved.

A lead frame for bonding to the IC die by printed-on solder or nanoparticle (NP) ink deposition is described. An IC die that may have solder or nanoparticle (NP) ink printed over through-silicon via (TSV) pads for low-down force wire bonding is described.

The complementary metal-oxide-semiconductor (CMOS) of a known-good-die (KGD) (e.g., clock tree, or PDN) may be removed from the IC die, and replaced with a respective clock tree or PDN chiplet mounted to a backside of the IC die. The clock tree or PDN chiplet may be mounted directly onto a redistribution layer (RDL) or pads and connected through through-silicon vias (TSVs) of the IC die. The clock tree or PDN chiplet, or both chiplets, may be mounted by wirebond or soldered to a lead frame, which is connected to the RDL or to pads of the IC die. Backside wirebond or lead frame connections to power, ground, and thermal mitigation may be routed through the RDL and TSVs to the main IC die. The lead frame may be soldered to a GAA die as well as soldered to the package substrate/printed circuit board (PCB).

A backside lead frame as described herein may be built upon any IC wired for power/ground through TSVs, and may be mounted onto a process on record (POR) substrate (PCB/package substrate). Power and ground from the backside of the wafer may improve FEOL metal layout and efficiency, as typically the power and ground lines have the largest critical dimensions (CDs), and as a result it may decrease resistance-capacitance (RC) problems. A CD in this context is a conductor line width measured on the order of microns (μm), because the power and ground lines may need to pass fast AC or DC-pulse current (on the order of nanoseconds) with a current on the order of several milliamperes.

Advanced technologies share very little processing with standard silicon MOSFETs making it extremely expensive to build “support transistors” on the same die used for advance technologies. Addition of sticky vias/pads in place of normal through-silicon via (TSV) pads may allow for reduced damage and improved bonding (of a KGD, a wire, pr lead frames) to the back-side of the IC die(s). Sticky flipchip contacts and sticky bonding elements may include a conduction component for providing a conductive connection with a complementary device (e.g., an IC die, interposer, or other IC package module) and a bonding component for forming a physical bond with the complementary device. Sticky vias/pads are fully disclosed in U.S. patent application Ser. No. 17/665,749 filed Feb. 7, 2022 and U.S. patent application Ser. No. 17/667,275 filed Feb. 8, 2022, the entire contents of which are hereby incorporated by reference for all purposes.

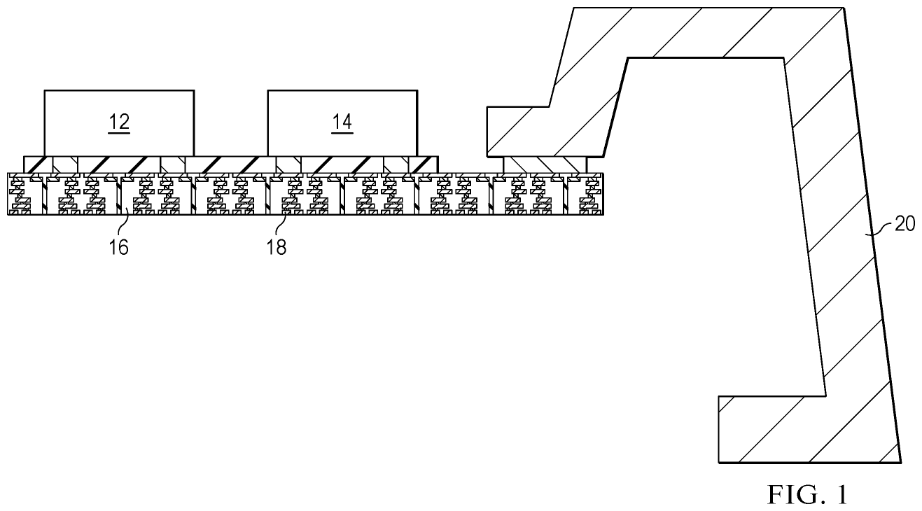

FIG. 1 shows a clock tree chiplet 12 and a power management chiplet 14 mounted to a redistribution layer 16 that has through-silicon vias 18. A stamped copper clip 20 electrically communicates with one of the through-silicon vias 18. In particular, two 8″ or 12″ analog CMOS chiplets 180 nm-28 nm, one for Clock Tree (buffer/driver/repeaters) and the other for Power Management (low drop-out linear regulators (LDO), dynamic voltage and frequency scaling (dvfs), without limitation). The PowerVia (20 Angstrom/18 Angstrom) die size may be reduced by moving the long channel (high power, I/O voltage large current) large area Power or Clock Tree to above the Power vIa Clock (PIC). PowerVia is a backside power delivery scheme by Intel Corporation. This configuration shown in FIG. 1 may enjoy (1) system on chip (SoC) resistance-capacitance (RC) M6˜M16 type delay and (2) reduce hot spots of IC dies (20 Angstrom/18 Angstrom and smaller).

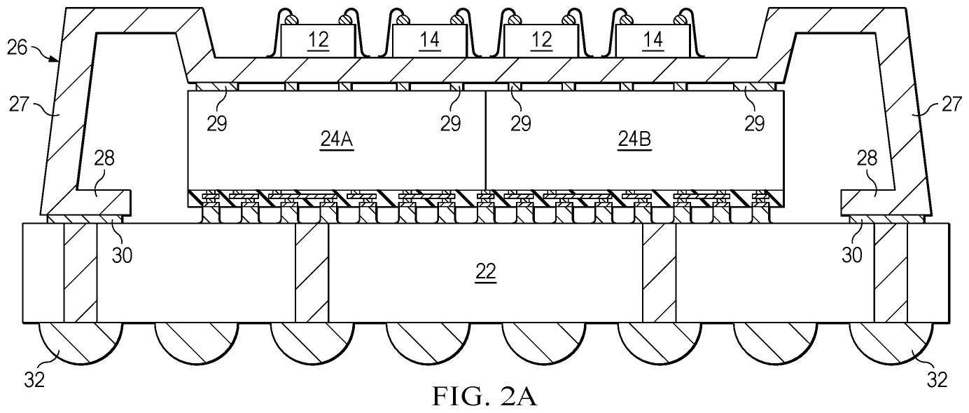

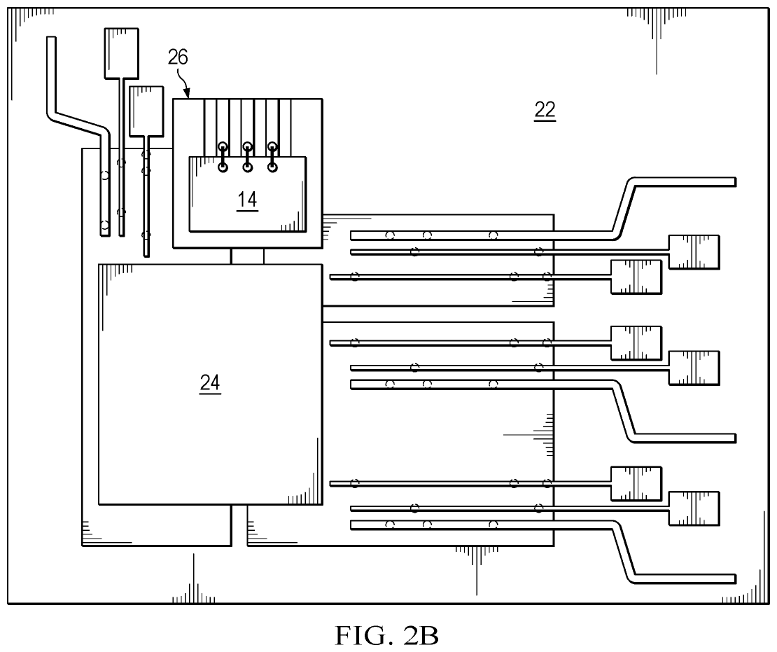

FIG. 2A shows a side view of a double side lead frame IC package with a backside power delivery architecture. A substrate 22 has two chips mounted thereon, chips 24A and 24B. A lead frame 26 is positioned over the chips 24A and 24B and substrate 22 to electrically communicate with both. The lead frame 26 has two side wiring contacts 28 extending from ends of copper leads 27. Chiplets 12 and 14 are placed, with chip pads of chiplets 12, 14 facing up, and chiplets 12, 14 are wire bonded to pads on the top-side of the lead frame 26. In particular, the chiplets 12 and 14 are pin-count KGDs and, as indicated above, are mounted to the lead frame 26 by wire bonding, which may provide thermal isolation for chiplets 12, 14 from chips 24A, 24B compared to front-side packages. Lead frame 26 may have two-side wiring contacts: (1) via sticky flipchip contacts 28 on the bottom of the lead frame 26, wherein the PIC output pad is face down; and (2) wire bond on the top-side, wherein the PIC's output pad is face up. The bonding surfaces of chip 24A, chip 24B, chiplets 12 and 14, or copper leads 27 may be coated in nanoparticle (NP) ink or solder. Ground or power may be provided through conductors, such as the copper leads 27 shown in FIG. 2A, wherein the copper leads 27 of the IC industry's standard package with Lead Frame size: 200 μm˜20 μm. A copper lead frame may be manufactured by very low cost stamping or by lithography etch, as the copper leads 27 may be larger in size compared to standard IC copper vias or interconnects. A top view of another IC package is shown in FIG. 2B, wherein a lead frame 26 has two-side wiring contacts: sticky flipchip contacts on the bottom of the lead frame 26 for making connections to the chip 24; and wire bond on the top of the lead frame 26 for making connections to the chiplet 14.

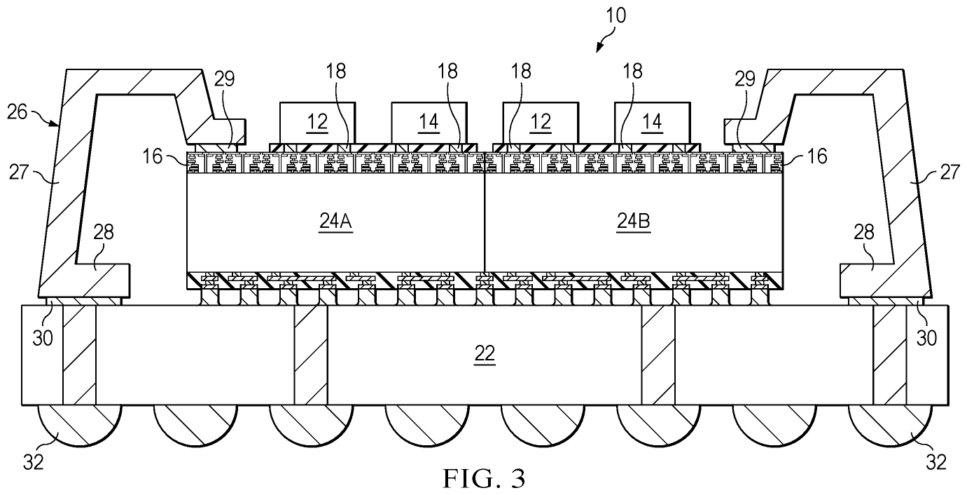

FIG. 3 illustrates a side view of a double side lead frame 26 for an IC package device and a bonding system for bonding the IC package device to other IC package devices in an IC package 10. Chip 24A and Chip 24B are respectively mounted on a substrate 22. According to one example, double side copper lead frame 26 provides for direct connection (not through a redistribution layer) to the substrate 22 and allows individual KGD chiplets 12 and 14 to be solder bonded or nanoparticle (NP) ink bonded to chip 24A and chip 24B. While chip 24A and chip 24B are solder ball mounted directly to the substrate 22, the double side copper lead frame 26 connects the tops of the chips 24A and 24B to the substrate 22 to provide a connection path through copper leads 27 for chiplets 12, 14. Chiplets 12 and 14 may be mounted directly to TSV pads 18 of Chip 24A and Chip 24B, as an alternative to the wire bond connections shown in FIG. 2A.

For some applications, the copper leads 27 of double side lead frame 26 may be a fat metal lead, such as 35K, 200K, wire bond, or a copper clip. The copper leads 27 may provide a path to the substrate 22 to provide a path for Power vIa Clock. Chiplets 12 and 14 may interface with the copper leads 27 through a redistribution layer 16 and through TSV pads 18.

An IC package including an IC package device and a bonding system may bond the IC package device to other IC package devices in an IC package for backside power delivery methods (RibbonFET) or fin-shaped field-effect transistor (FinFET) transistor architectures. Some bonding systems may have 50 GHz wire bond. The bonding system may include a double-side lead frame 26 with sticky flipchip contacts on the bottom and wire bond contacts on the top.

Referring to FIG. 3, the double sided lead frame 26 may be on an organic substrate 22. The copper leads 27 may be bonded by solder paste or print Sn pre-dip, or molten Sn pre-dip to make bonds 29 with the redistribution layer 16 or bonds 30 with the substrate 22. Further, chips 24A and 24B may be any number of ASIC-AI chiplets communicating with the redistribution layer 16 to make a data center AI-retrain chiplet 2 nm→1 nm.

The double sided lead frame 26 may be bonded by solder paste or print Sn pre-dip, or molten Sn pre-dip on the substrate 22, before bump balls 32 are added to the bottom of the substrate 22. A data center AI-retrain single or 2 or 4 chiplets 2 nm→1 nm uBump may be added on a Nan Ya or Kyocera substrate 22 before bump balls 32 are added.

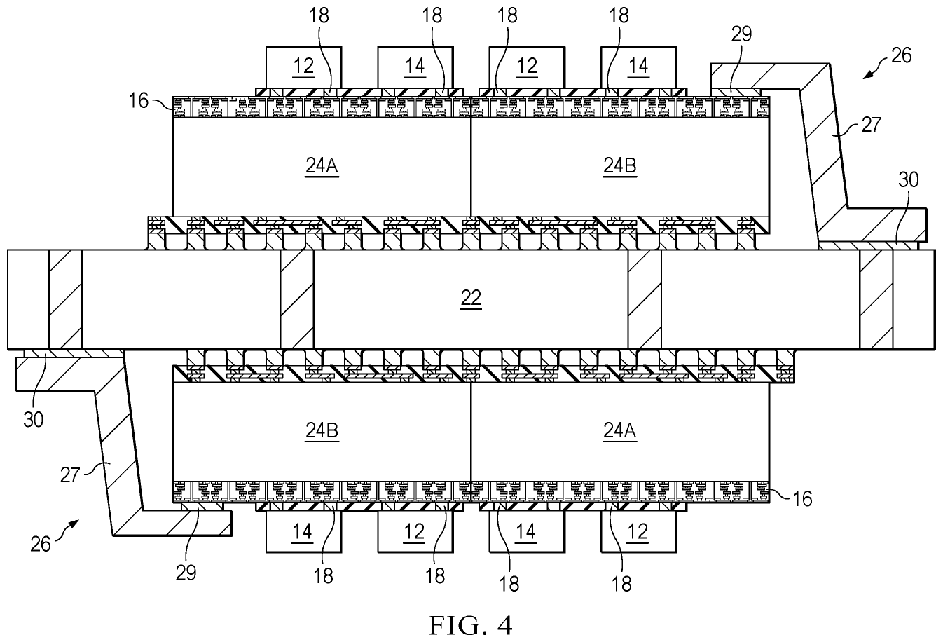

FIG. 4 shows a side view of a two-side (two lead frame) QFN package, where a lead frame 26 (backside copper clip or lead) provides a path for Power vIa Clock on both sides of the substrate 22. A two-sided QFN package may be applicable to analog power IC products and time clock IC products, such as KGD of AI-ASIC (2 nm→1 nm). The substrate 22 has two chips 24A and 24B mounted on a top surface of substrate 22 and two chips 24A and 24B mounted on a bottom surface of substrate 22. A first copper lead 27 makes connections between the top chips 24A and 24B and the substrate 22, and a second copper lead 27 makes connections between the bottom chips 24A and 24B and the substrate 22.

Certain examples provide for a copper lead frame with Sn-dip on any kinds of interposer (polymer, through glass via (TGV), Al₂O₃ interposer and silicon interposer).

In some examples, a clock Tree KGD ASIC (produced with 55 nm process) with MEMS may be implemented rather than a traditional and fishbone CTS characteristics (Mentor). Clock tree and clock mesh structures may both be used for Power vIa Clock (PIC). After Si-TCV back-side grinding, then KGD of a fishbone clock tree may be die bonded. Power Via Clock (PIC) may make SoC (M1˜M12) greater than 80% lower energy, and may also provide for high bandwidth Data Traffics. Power vIa Clock (PIC) may make Die-Bonding (tsv-STI) a few KGDs for Fish-Clock-Mesh and LDO (various Vdd, Sub-Vdd and GND). Power vIa Clock (PIC) may make RDL of Interposer-Pair become very low power and may also provide a very high data bandwidth (S/N and Byte error rate). Power vIa Clock (PIC) may have a few (sticky very big width >100 um) Lead-Frames to Wire (re-Sync) PIC back to an Interposers' redistribution layer RDL. This Power vIa Clock (PIC) can bring hundreds of micron copper distance of PCB or interposer technology to nanometer copper distance. Huge RC delay and energy consumption of copper interconnect between Moore′ die and Clock die or Power-IC can be achieved.

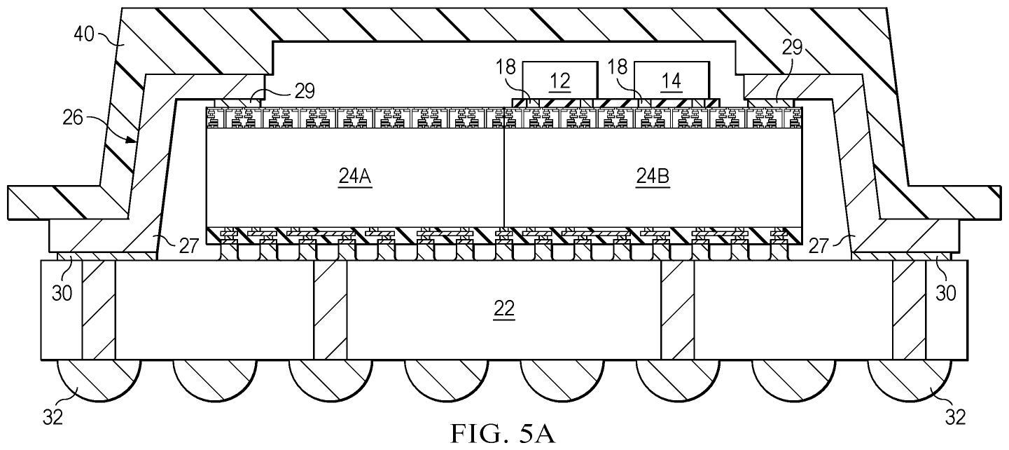

FIGS. 5A and 5B show side views of a dish for holding the copper lead frame in position to make the package. The dish 40 may hold and align the copper lead frame 26 and apply a downward force on the lead frame 26 to form bonds 29 with the chips 24A and 24B and to form bonds 30 with the substrate 22. In FIG. 5A, the dish 40 is in contact with the lead frame 26 to hold it against chips 24A and 24B and against the substrate 22 to allow for bonding. In FIG. 5B, the dish 40 is pulled away from the IC package after bonding is complete.

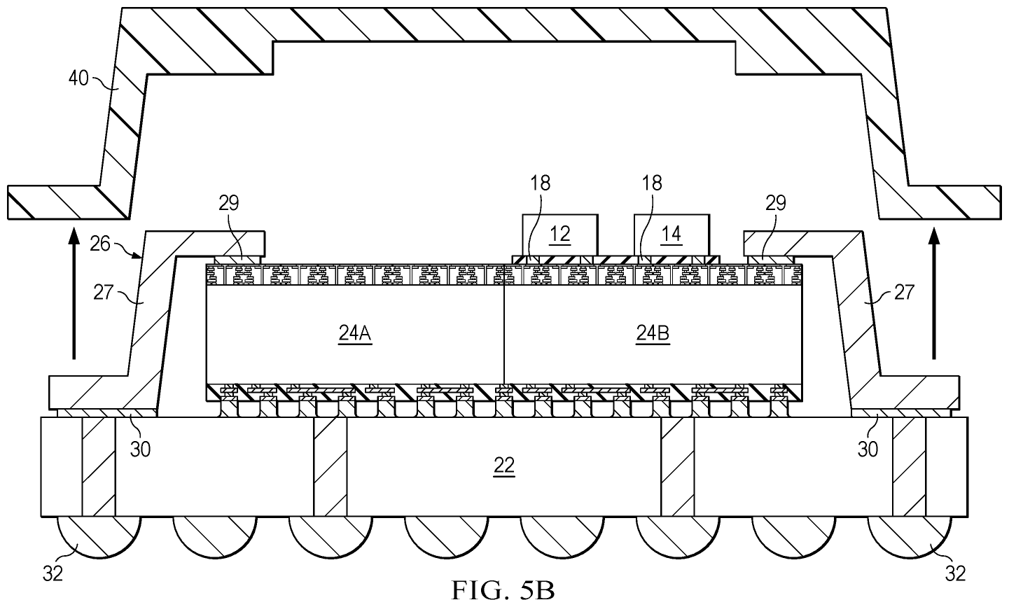

FIG. 6 shows a cross-sectional side view of an example tape 42 with a flexible/conductive ink print layer 44, a flexible/insulator print layer 46, and nanoparticle (NP) ink or Sn solder print layer 48 for bonding the copper lead frame.

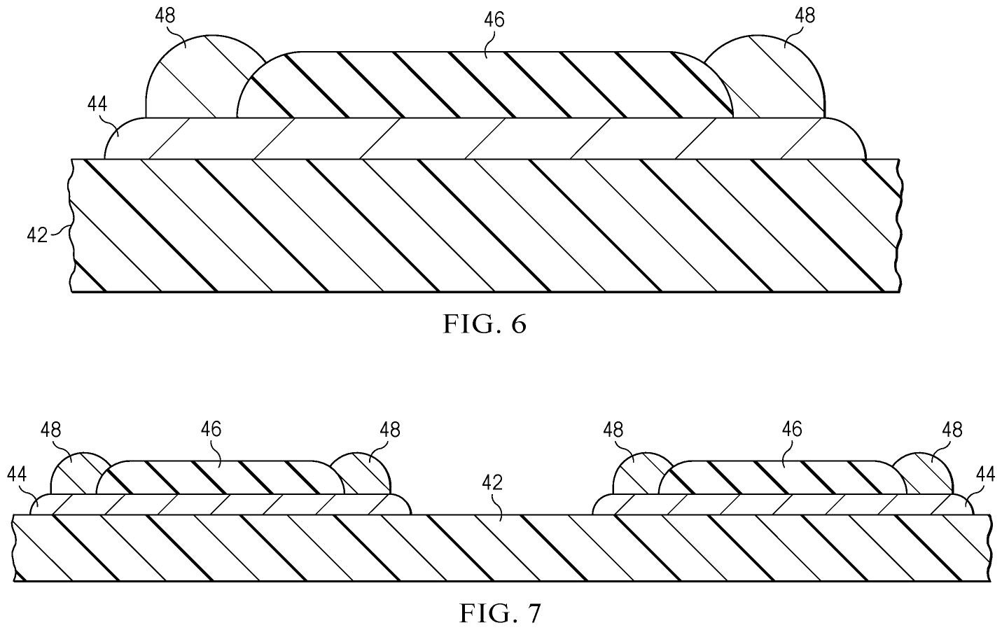

FIG. 7 is a cross-sectional side view of an example tape 42, with a flexible/conductive ink print layer 44, a flexible/insulator print layer 46, and nanoparticle (NP) ink or Sn/solder print layer 48 are printed on the flexible tape 42 in a pattern for bonding the copper lead frame.

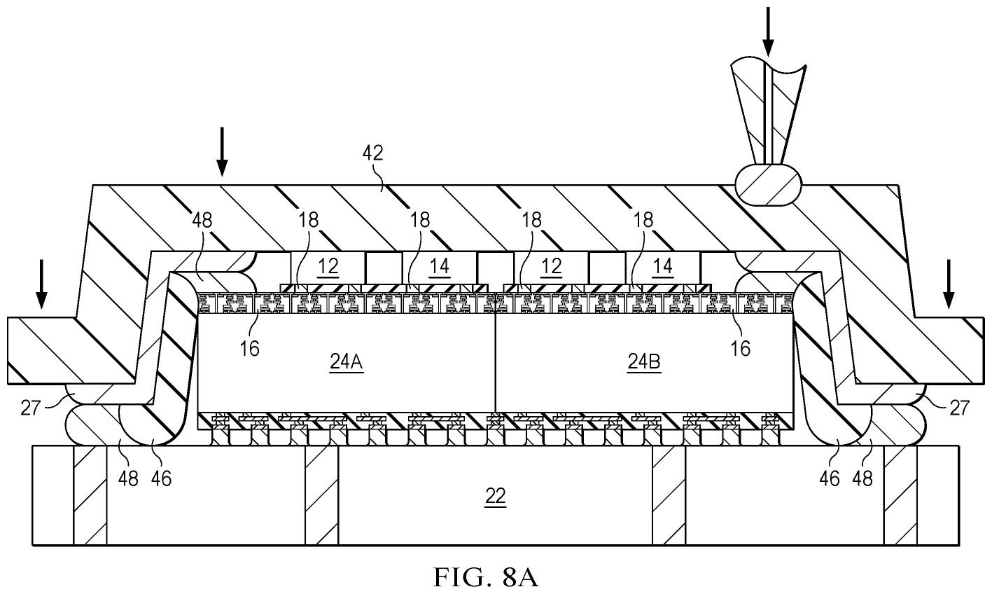

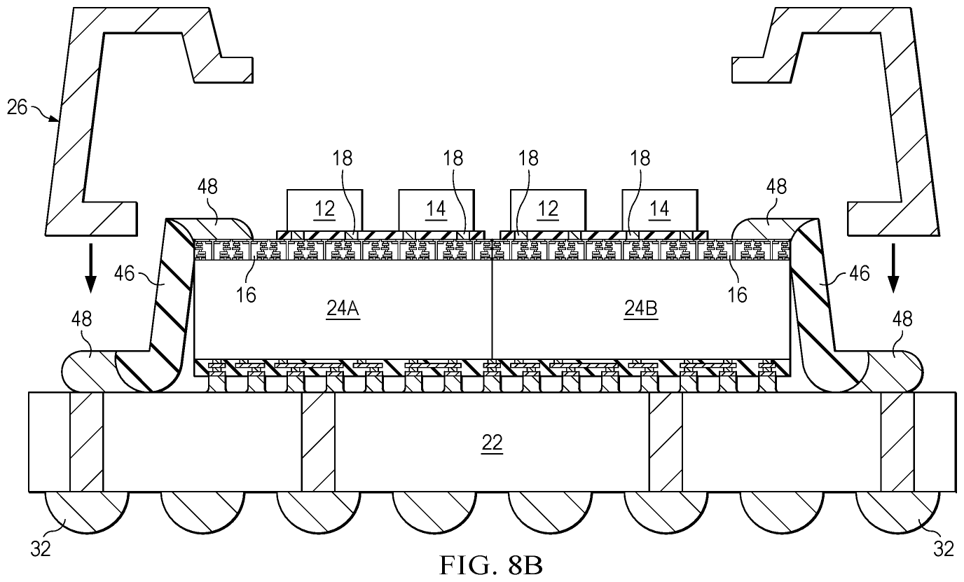

FIG. 8A shows a cross-sectional side view of an IC package, where a flexible tape 42 is aligned and placed over the entire IC package for bonding the copper lead frame. The ink or solder layer 48 is positioned in contact with the chips 24A and 24B, i.e. flipped in relation to FIGS. 6-7. The ink or solder layer 48 is also positioned in contact with the substrate 22. An insulator layer 46 is positioned to insulate the chips 24A and 24B from the lead frame 27 as the tape 42 is pressed down onto the package. Downward force is applied to the tape 42 on each bond to activate nanoparticle (NP) bonding of the copper lead frame 26.

FIG. 8B shows a cross-sectional side view of an alternative package compared to the package of FIG. 8A. The package of FIG. 8B has a flexible/insulator print layer 46, and nanoparticle (NP) ink or Sn solder print layer 48 are positioned on the IC package, i.e. directly on a portion of chip 24A, 24B and substrate 22, and the lead frame 26 is brought into position for bonding to the package. FIG. 3 shows a cross-sectional side view of the final IC package, wherein the lead frame 26 is bound to the chips 24A and 24B at bonds 29 and the lead frame 26 is bound to the substrate 22 at bonds 30.

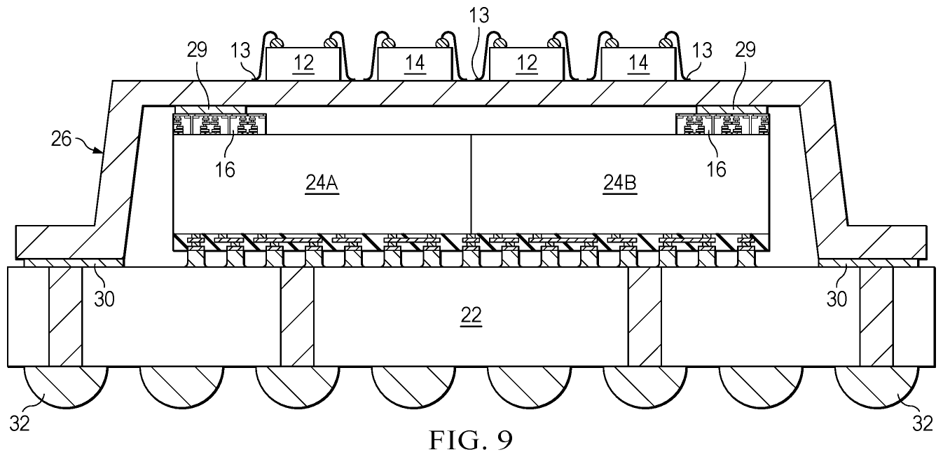

FIG. 9 shows a cross-sectional side view of a package wherein a flexible tape 42 (see FIG. 8A) bonds a leadframe 26 to the substrate 22 and to chips 24A and 24B. After placement, a heated probe may be used to modify the wire bond head 13. FIG. 9 further shows chiplets 12, 14 wire bonded to the lead frame 26 so the electrical connection to the substrate 22 is through the copper lead frame 26. As shown the lead frame 26 has attachments to chip 24A and chip 24B, and the chiplets 12 and 14 attach to the lead frame 26 via 4-7 pin.

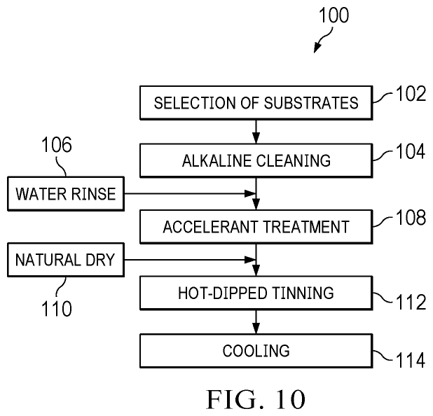

FIG. 10 illustrates an algorithm 100 for pre-coating solder paste on an organic substrate's power redistribution layer for bonding a copper clip or lead frame. The copper lead frame may be shipped with manual Sn-dip and tweezer-placing after an integrated fan-out assembly on substrate (InFO-OS) (see FIG. 4). Tweezer-placing comprises the steps and tools for attaching respective chiplets 12, 14 on the backside of chips 24A, 24B so that both chips 24A, 24B may have the functionality of chiplets 12, 14. In one example, as indicated above, chiplets 12, 14 may be respectively a clock tree or a Power Distribution Network (PDN). A hot-dipped tinning process routine may be used for copper lead frames. The substrates are first selected 102, wherein the substrates may be organic material selected based on good (1) insulation polymer with (2) tight pitch (<50 μm) copper conducting traces, and (3) solder-paste may be pre-applied without defects or current leakage. The substrates or lead frames are then subjected to alkaline cleaning 104. The substrates or lead frames may then be rinsed 106 with water. The substrates or lead frames may then be subjected to accelerant treatment 108. The components are then dried naturally 110 via evaporation to ambient air. The substrates or lead frames are then hot-dipped tinned 112. Finally, the components are cooled 114.

In some applications, solder may be replaced with all-copper interconnects.

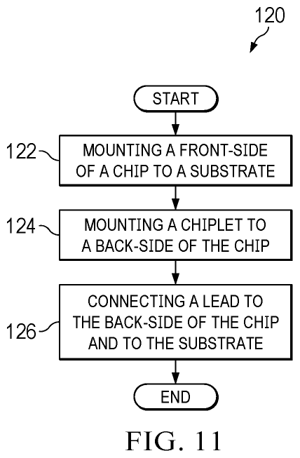

FIG. 11 illustrates an fabrication method 120 for manufacturing an IC package including an IC package device and a bonding system for bonding the IC package device to other IC package devices in an IC package. The bonding system may include a double-side lead frame with sticky flipchip contacts on the bottom and wire bond contacts on the top. The fabrication method 120 may begin by mounting 122 a front-side of a chip to a substrate. Next, a chiplet is mounted 124 to a back-side of the chip, wherein the chiplet may have a clock tree circuit, a power distribution network circuit, or a low drop-out linear power management regulator circuit. A lead is connected 126 to the back-side of the chip and to the substrate, wherein the lead is capable of conducting power to the chip from the substrate

A redistribution layer may be mounted or deposited on the back-side of the chip and a chiplet may be mounted to the back-side of the redistribution layer. The chip may be electrically connected to the chiplet through a through-silicon via in the redistribution layer. The lead may be mounted to the back-side of the chip and the chiplet mounted to the lead, and the chiplet may be wire bound to the lead. The chiplet may be mounted to the backside of the chip by soldering the chiplet to the lead.

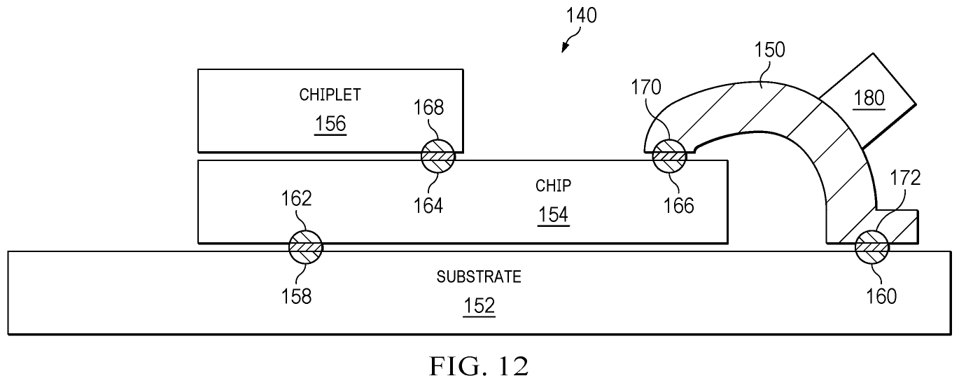

FIG. 12 illustrates a schematic diagram of an IC package 140. The IC package 140 has a substrate 152 having a first substrate contact 158 and second substrate contact 160. A chip 154 is mounted to the substrate 152 and has a front-side chip contact 162, a first back-side chip contact 164, and a second back-side chip contact 166. The front-side chip contact 162 may be electrically connected to the first substrate contact 158. A chiplet 156 is mounted to the chip 154 and has a chiplet contact 168 electrically connected the first back-side chip contact 164. The chiplet may have a clock tree circuit, a power distribution network circuit, or a low drop-out linear power management regulator circuit, without limitation. A lead 150 has a first lead contact 170 connected to the second back-side chip contact 166 and a second lead contact 172 connected to the second substrate contact 160. The lead 150 may be connected to a thermal mitigation device 180, such as a passive air-cooled heat sink or an active heat exchanger driven by water, methanol, or ethanol.

Although examples have been described above, other variations and examples may be made from this disclosure without departing from the spirit and scope of these disclosed examples.

1. An apparatus comprising:
a substrate having first and second substrate contacts;
a chip having a front-side chip contact and first and second back-side chip contacts, the front-side chip contact electrically connected to the first substrate contact;
a chiplet having a chiplet contact electrically connected the first back-side chip contact; and
a lead electrically connected to the second back-side chip contact and electrically connected to the second substrate contact.

2. The apparatus as claimed in claim 1, wherein the chiplet comprises a circuit selected from a clock tree, a power distribution network, and a low drop-out linear power management regulator

3. The apparatus as claimed in claim 1, wherein the chiplet contact is electrically connected to the first back-side chip contact via the lead, the chiplet contact is wire bonded to the lead, and the lead is electrically connected to the first back-side chip contact.

4. The apparatus as claimed in claim 1, comprising a redistribution layer having front-side and back-side redistribution contacts, wherein the chiplet contact is electrically connected to the first back-side chip contact via the redistribution layer, wherein the front-side redistribution contact is electrically connected to the first back-side chip contact and the back-side redistribution contact is electrically connected to the chiplet contact.

5. The apparatus as claimed in claim 3, wherein the redistribution layer comprises a through-silicon via electrically connecting the front-side and back-side redistribution contacts.

6. The apparatus as claimed in claim 1, wherein the chip is connected to a power source through the lead.

7. The apparatus as claimed in claim 1, wherein the chip is electrically connected to a ground through the lead.

8. The apparatus as claimed in claim 1, wherein the chip is electrically connected to a thermal mitigation device through the lead.

9. A method comprising:
mounting a front-side of a chip to a substrate, wherein the chip has a front-side chip contact and first and second chip back-side contacts and the substrate has first and second substrate contacts;
electrically connecting the front-side chip contact to the first substrate contact;
mounting a chiplet to a back-side of the chip, wherein the chiplet has a chiplet contact;
electrically connecting the chiplet contact to the first chip back-side contact; and
electrically connecting a lead to the second back-side chip contact and to the second substrate contact, wherein the lead is capable of conducting power to the chip.

10. The method as claimed in claim 9, wherein the chiplet comprises a circuit selected from a clock tree, a power distribution network, and a low drop-out linear power management regulator.

11. The method as claimed in claim 9, wherein the mounting the chiplet to the back-side of the chip comprises mounting a redistribution layer on the back-side of the chip and mounting the chiplet to the redistribution layer.

12. The method as claimed in claim 11, comprising electrically connecting the chip to the chiplet through a through-silicon via in the redistribution layer.

13. The method as claimed in claim 9, wherein the mounting the chiplet to the back-side of the chip comprises mounting the lead to the back-side of the chip and mounting the chiplet to the lead, and comprising wire bonding the chiplet to the lead.

14. The method as claimed in claim 11, wherein the mounting the chiplet to the backside of the chip comprises soldering the chiplet to the lead.

15. The method as claimed in claim 11, comprising connecting the lead to a thermal mitigation device.

16. A system comprising:
a substrate having first and second substrate contacts;
a chip having a front-side chip contact and first, second, and third back-side chip contacts, the front-side chip contact electrically connected to the first substrate contact;
a clock tree chiplet having a clock tree chiplet contact electrically connected the first back-side chip contact, wherein the clock tree chiplet comprises a clock tree circuit;
a power distribution network chiplet having a power distribution network contact electrically connected the third back-side chip contact, wherein the power distribution network chiplet comprises a power distribution network circuit; and
a lead electrically connected to the second back-side chip contact and electrically connected to the second substrate contact.

17. The system as claimed in claim 16, wherein the clock tree chiplet contact is electrically connected the first back-side chip contact via the lead, the clock tree chiplet contact is wire bonded to the lead, and the lead is electrically connected to the first back-side chip contact.

18. The system as claimed in claim 16, wherein the power distribution network contact is electrically connected the chip back-side third contact via the lead, the power distribution network chiplet contact is wire bonded to the lead, and the lead is electrically connected to the first back-side chip contact.

19. The system as claimed in claim 16, comprising a redistribution layer having a front-side and a back-side redistribution contact, wherein the clock tree chiplet contact is electrically connected to the first back-side chip contact via the redistribution layer, wherein the front-side redistribution contact is electrically connected to the first back-side chip contact and the back-side redistribution contact is electrically connected to the clock tree chiplet contact, wherein the redistribution layer comprises a through-silicon via electrically connecting the front-side and back-side redistribution contacts.

20. The system as claimed in claim 16, comprising a redistribution layer having a front-side and a back-side redistribution contact, wherein the power distribution network chiplet contact is electrically connected to the third back-side chip contact via the redistribution layer, wherein the front-side redistribution contact is electrically connected to the third back-side chip contact and the back-side redistribution contact is electrically connected to the power distribution network chiplet contact, wherein the redistribution layer comprises a through-silicon via electrically connecting the front-side and back-side redistribution contacts.

21. The system as claimed in claim 16, wherein the chip is electrically connected to a power source through the lead.

22. The system as claimed in claim 16, wherein the chip is electrically connected to a ground through the lead.
